(19) United States
(12) Patent Application Publication
(10) Pub. No.: US 2026/0313935 A1
(43) Pub. Date: Oct. 8, 2026

(54) DEFECT FREE LOW TEMPERATURE JUNCTION FORMATION FOR 4F2 DRAM

(71) Applicant: Applied Materials, Inc., Santa Clara, CA (US)

(72) Inventors: Zhijun CHEN, San Jose, CA (US); Raghuveer Satya MAKALA, Santa Clara, CA (US)

(21) Appl. No.: 19/630,248

(22) Filed: Mar. 26, 2026

Related U.S. Application Data
(60) Provisional application No. 63/805,998, filed on May 15, 2025.
(60) Provisional application No. 63/783,417, filed on Apr. 4, 2025.

(51) Int. Cl. H10D 30/01; H10B 12/00; H10D 30/63; H10D 62/83; H10P 30/20; H10P 30/28

(52) U.S. Cl. CPC H10D 30/025; H10B 12/33; H10D 30/63; H10D 62/83; H10P 30/204; H10P 30/28

(57) ABSTRACT

A method of forming a semiconductor structure, comprising: removing a portion of a first dielectric layer, which surrounds a plurality of channel layers, to expose portions of the plurality of channel layers; implanting a dopant into the exposed portions of the plurality of channel layers to form a first doped region within each of the plurality of channel layers; forming a second dielectric layer over the first doped regions; and forming a second doped region on an exposed portion of each of the first doped regions disposed within the second dielectric layer.

### CROSS-REFERENCE TO RELATED APPLICATIONS

This application claims priority to United States Provisional Applications Serial No. 63/783,417 filed Apr. 4, 2025, and Serial No. 63/805,998 filed May 15, 2025, each of which is herein incorporated by reference in its entirety.

### BACKGROUND

### FIELD

Embodiments described herein generally relate to semiconductor device fabrication, and more particularly, to methods of forming bit line junctions in 4F² (feature square) dynamic random access memory (DRAM) devices.

### Description of the Related Art

The production of silicon integrated circuits has placed difficult demands on fabrication processes to increase the number of devices while decreasing the minimum feature sizes on a chip. These demands have extended to fabrication processes including depositing layers onto difficult topologies while maintaining device reliability. For example, 4F² (feature square) dynamic random access memory (DRAM) devices are an economical way to scale DRAM devices before 3D DRAM becomes a reality. Unlike current 6F² DRAM where a cell transistor is U-shaped with both source and drain on the same side, the source and drain are at opposite sides of a vertical transistor in 4F² DRAM. As a result, source/drain junctions for bit lines and cell capacitors are often formed at different stages of the flow.

Unfortunately, the thermal budget needed for junction formation and activation may not be compatible with the components that were fabricated upstream. For example, one of the more practical schemes for forming 4F² DRAM devices involves fabricating capacitors first then flip the wafer to form bit lines. In this case, the bit line junction formation becomes challenging because of the thermal budget constraint to protect capacitor high-k dielectric material, for example, below 450° C.

Due to the thermal budget constraint, the traditional diffusion followed activation approach to form lightly doped drain (LDD) region faces challenges. Existing technologies such as P-doped poly-crystalline Si deposition, implant, epitaxial growth, laser anneals, and/or combinations of such cannot meet the stringent requirements, namely precise dopant concentration and diffusion profile control with minimum defect generation under 450°C. Ideally, the junction regions should have active dopant concentration gradually transitioned from a lightly doped drain (LDD) region (e.g., greater than about 10¹⁸ cm⁻³ or about 10¹⁹ cm⁻³) for drive current enhancement to almost metallic (e.g., higher than about 10²⁰ cm⁻³) for contact resistance Rc reduction. Further, the LDD regions need to remain defect free to minimize gate induced drain leakage (GIDL).

Therefore, there is a need for low temperature processes for forming low defect source/drain junctions for cell transistors without sacrificing dopant concentration or junction profile.

### SUMMARY

Embodiments of the present disclosure provide a method of forming a semiconductor structure. The method includes removing a portion of a first dielectric layer, which surrounds a plurality of channel layers, to expose portions of the plurality of channel layers; implanting a dopant into the exposed portions of the plurality of channel layers to form a first doped region within each of the plurality of channel layers; forming a second dielectric layer over the first doped regions; and forming a second doped region on an exposed portion of each of the first doped regions disposed within the second dielectric layer.

Embodiments of the present disclosure also provide a method of forming a semiconductor structure. The method includes partially recessing a first dielectric layer surrounding channel layers to partially expose portions of the plurality of channel layers; implanting a dopant into the exposed portions of the plurality of channel layers to form first doped regions within the exposed portions of the plurality of channel layers; forming a second dielectric layer over the first doped regions; recessing a portion of the first doped regions within the second dielectric layer, creating self-aligned contact holes in the second dielectric layer; and forming second doped regions within the self-aligned contact holes in the second dielectric layer.

Embodiments of the present disclosure further provide a method of forming a semiconductor structure. The method includes recessing a first dielectric layer isolating main gates from a plurality of channel layers in a first direction, main gate dielectric layers isolating the main gates in a second direction that is orthogonal to the first direction, a second dielectric layer disposed on above and below back gages in the second direction, and back gate dielectric layers disposed on both sides of each of back gates in the second direction, to partially expose portions of the plurality of channel layers; implanting a dopant into the exposed portions of the plurality of channel layers to form first doped regions; forming a third dielectric layer over the first doped regions; and forming a second doped regions on the first doped regions within the third dielectric layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a cluster tool, according to one or more embodiments of the present disclosure.

FIG. 2 depicts a process flow diagram of a method of forming low thermal budget low defect source/drain junction with LDD and low contact resistance Rc regions for 4F² DRAM with vertical cell transistors.

FIGS. 3A1, 3A2, 3B1, 3B2, 3B3, 3B4, 3C1, 3C2, 3C3, 3C4, 3D, 3E, and 3F are schematic views of a portion of a semiconductor structure corresponding to various states of the method of FIG. 2.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods of forming low defect source/drain junctions for cell transistors without sacrificing dopant concentration or junction profile in 4F² (feature square) dynamic random access memory (DRAM) devices.

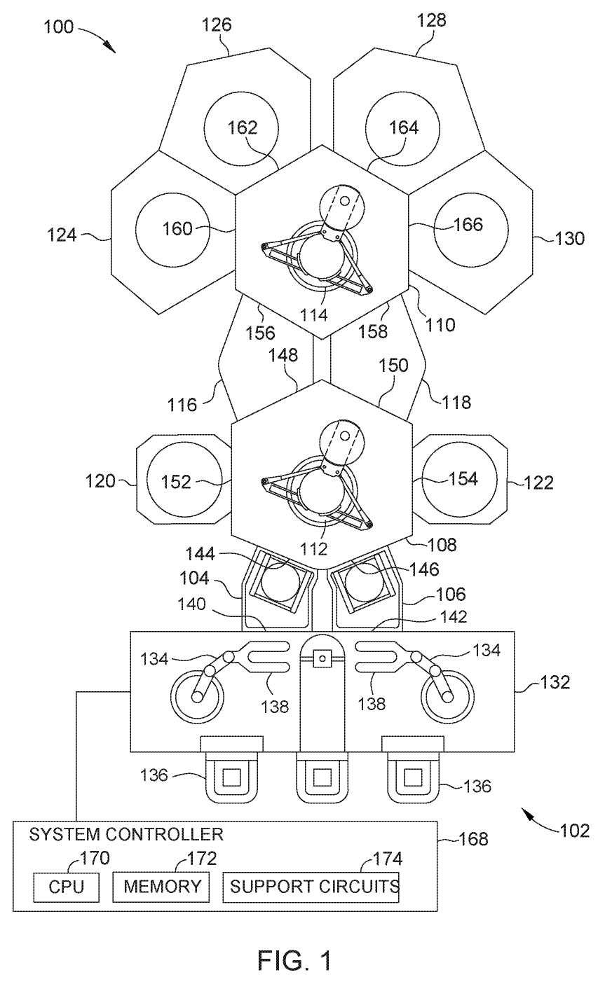

FIG. 1 is a schematic top view of a multi-chamber cluster tool 100, according to one or more embodiments of the present disclosure. The cluster tool 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the cluster tool 100 can be processed in and transferred between the various chambers without exposing the substrates to an ambient environment exterior to the cluster tool 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the cluster tool 100. Accordingly, the cluster tool 100 may provide for an integrated solution for some processing of substrates.

Examples of a cluster tool that may be suitably modified in accordance with the teachings provided herein include the Endura^{®}, Producer^{®} or Centura^{®} integrated cluster tools or other suitable cluster tools commercially available from Applied Materials, Inc., located in Santa Clara, California. It is contemplated that other cluster tools (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158,160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes or atomic layer deposition (ALD) processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z^{TM} chamber available from Applied Materials of Santa Clara, Calif. The processing chamber 128, or 130 may be a Centura™ Epi chamber available from Applied Materials of Santa Clara, Calif.

A system controller 168 is coupled to the cluster tool 100 for controlling the cluster tool 100 or components thereof. For example, the system controller 168 may control the operation of the cluster tool 100 using a direct control of the chambers 104, 106, 108, 110, 116, 118, 120, 122, 124, 126, 128, 130 of the cluster tool 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the cluster tool 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other cluster tools can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a cluster tool.

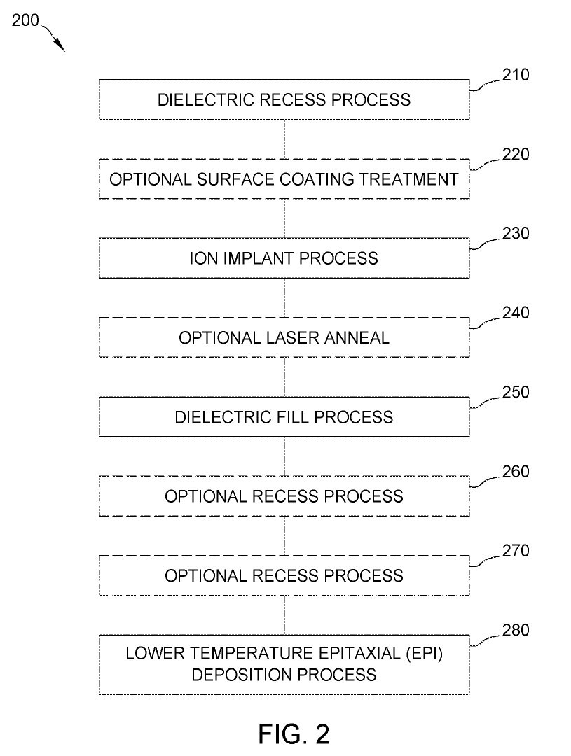

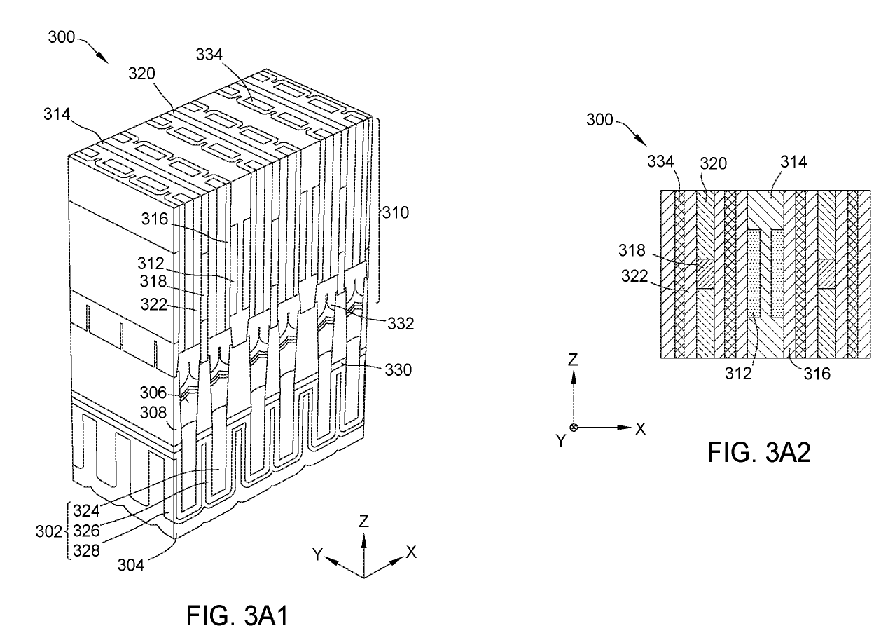

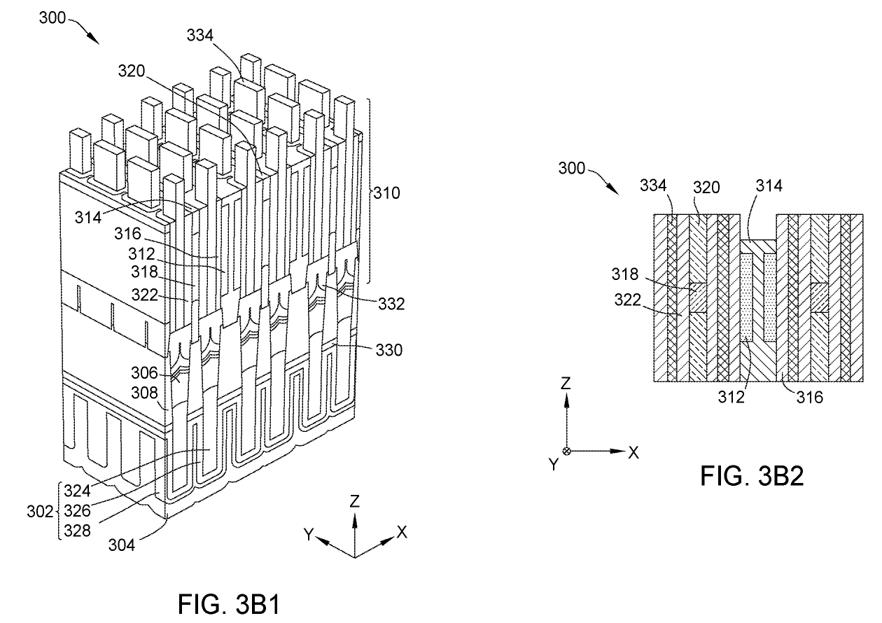

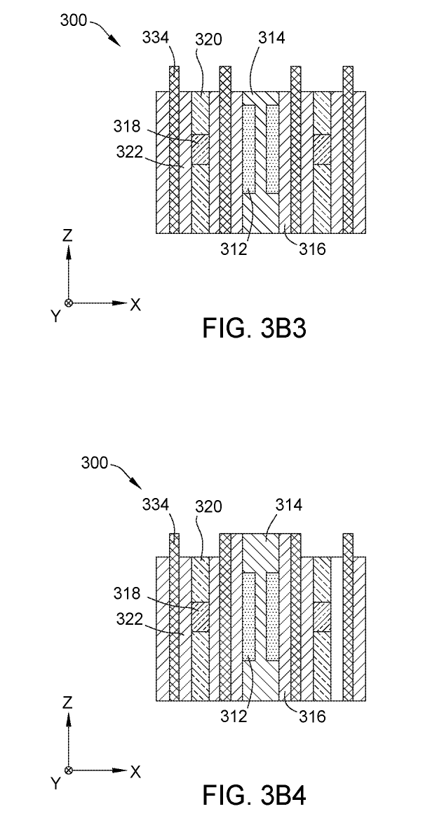

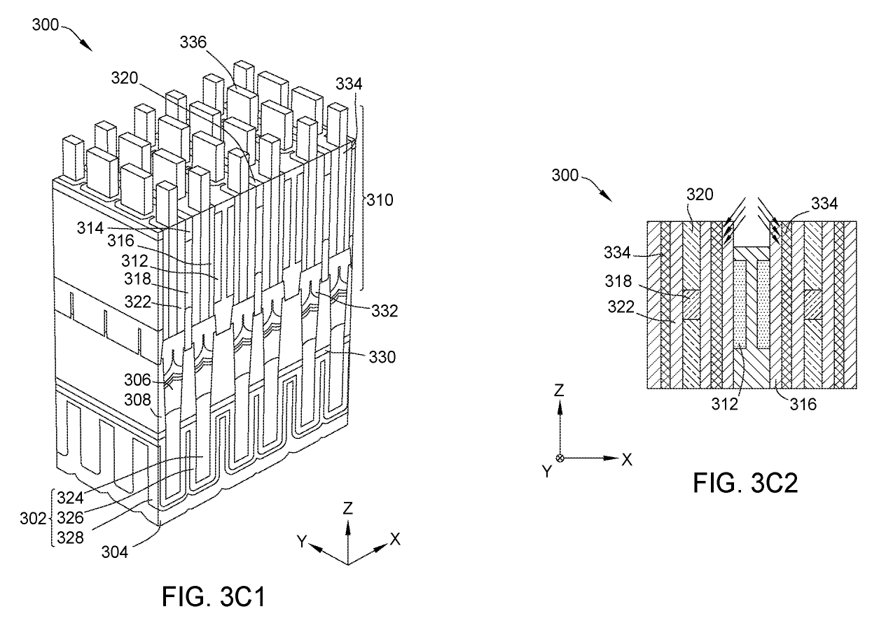

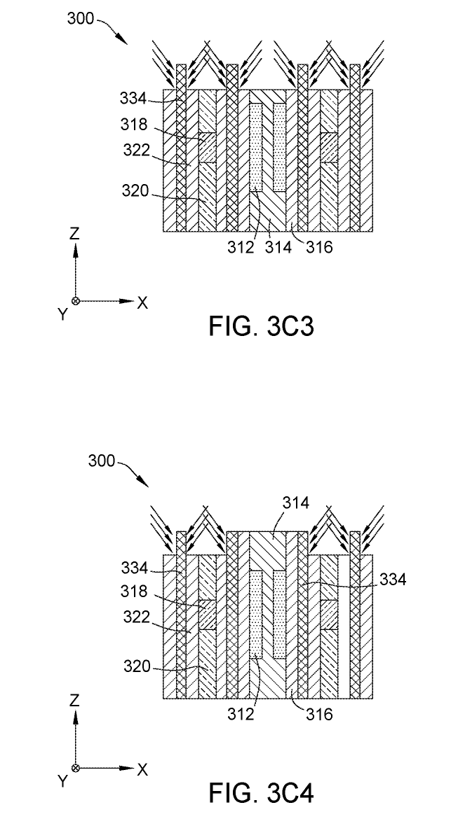

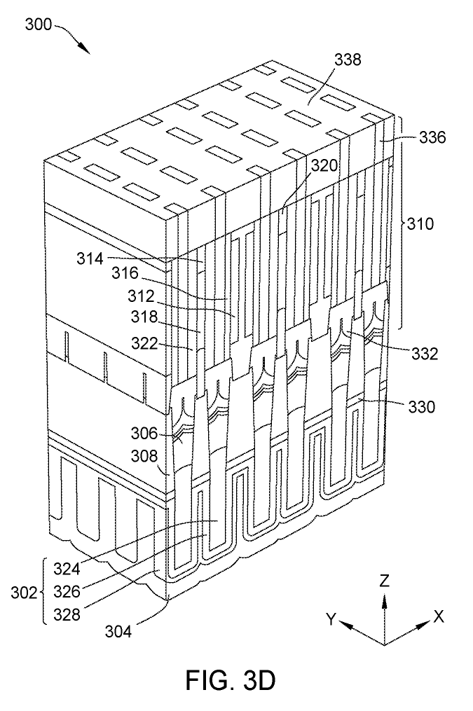

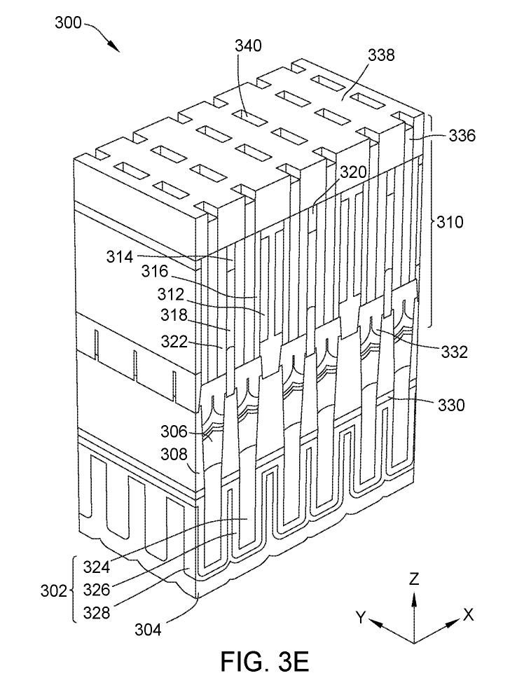

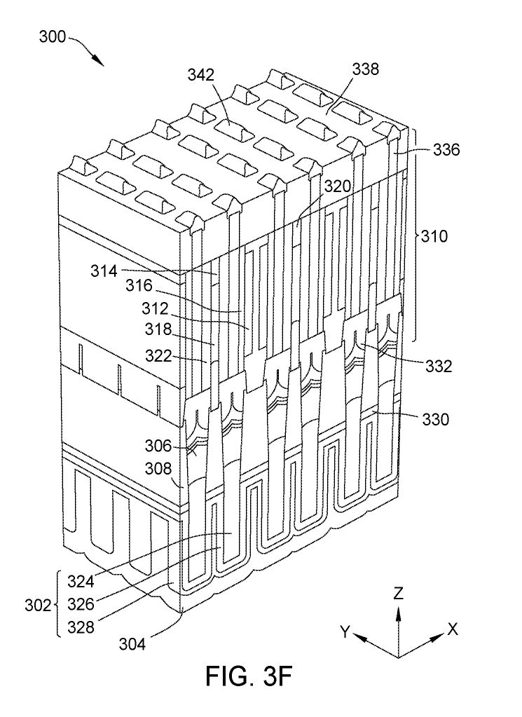

FIG. 2 depicts a process flow diagram of a method 200 of forming a source/drain junction under low thermal budget in a semiconductor structure 300 forming a portion of a 4F² DRAM device that includes vertically arranged channel transistors, according to one or more embodiments of the present disclosure. FIGS. 3A1, 3B1, 3C1, 3D, and 3E, are perspective views of a portion of the semiconductor structure 300 corresponding to various states of the method 200. FIGS. 3A2, 3B2, 3B3, 3B4, 3C2, 3C3, and 3C4 are enlarged cross-sectional views of a portion of the semiconductor structure 300. It should be understood that FIGS. 3A,1, 3B1, and 3C1 illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein. The embodiments of the disclosure are described by way of the Figures, which illustrate devices (e.g., a 4F² DRAM with vertical cell transistors) and processes for forming devices in accordance with one or more embodiments of the disclosure. The processes shown are merely illustrative possible uses for the disclosed processes, and the skilled artisan will recognize that the disclosed processes can be applied to other devices in which bitlines can be formed first for certain device design reasons low thermal budget is needed to form the junction for capacitors.

The semiconductor structure 300 shown in FIGS. 3A1 and 3A2 includes a capacitor structure 302 surrounded by a Ge-containing layer 304, a storage node contact 306 surrounded by a first dielectric layer 308 in the X direction, cell transistors 310, word lines (also referred to as “main gates”) 312 isolated from channel layer 334 by a second dielectric layer 314 in the Z direction and main gate dielectric layers 316 in the X direction, and back gates 318 having a third dielectric layer 320 on above and below the back gates 318 in the Z direction and back gate dielectric layers 322 on both sides of each of the back gates 318 in the X direction, formed on a substrate (not shown). In some cases, the back gate 318 may be in the form of an air gap with or without the back gate dielectric layers 322. In other cases, the second dielectric layer 314 may also be in the form of an air gap. In yet another case, both the back gate 318 and the second dielectric layer 314 may be in the form of air gaps. In addition, the second dielectric layer 314 may have different compositions across the channel height. Namely, the portion that is sandwiched by the word lines 312 may be different from the portions above or below the word lines 312.

The capacitor structure 302 includes a first electrode 324, a capacitor dielectric layer 326, and a second electrode 328, which are sequentially stacked. Therefore, the capacitor dielectric layer 326 may be interposed between the first electrode 324 and the second electrode 328. The capacitor structure 302 may store data (e.g., charges) in the capacitor dielectric layer 326 by using a potential difference generated between the first electrode 324 and the second electrode 328.

In some embodiments, a liner layer 330 is interposed between the first dielectric layer 308 and the capacitor structure 302. The liner layer 330 may serve as an etch stop layer in an etching process for forming the capacitor structure 302.

The first dielectric layer 308, the second dielectric layer 314, and the third dielectric layer 320 may be formed of silicon nitride (Si₃N₄), silicon oxide (SiO₂), silicon oxynitride (SiNₓO_{y}), a low-k material having a dielectric constant lower than that of the silicon oxide (SiO₂), or any combination thereof. The storage node contact 306 may be made of formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, WSi, MoSi, CoSi, IrOx, RuOx, or any combination thereof.

The main gate dielectric layers 316 and the back gate dielectric layers 322 may be formed of silicon oxide (SiO₂), silicon oxynitride (SiNₓO_{y}), silicon oxycarbide (SiOₓC_{y}), silicon-oxycarbonitride (SiOCN), a high-k material, or any combination thereof. The main gate dielectric layers 316 have a thickness of between about 3 nm and about 6 nm in the X direction. The back gate dielectric layers 322 may have a thickness of between about 1 nm and about 8 nm in the X direction.

The first electrode 324 and the second electrode 328 may be formed of doped polysilicon, metals, conductive metal nitride, conductive metal silicide, conductive metal oxide, or any combination thereof.

The cell transistor 310 includes first source/drain (S/D) junction regions 332, which are arranged with the channel layers 334 along the Z direction. The cell transistor 310 including the first S/D junction region 332, a second S/D junction region to be formed on the other end in the Z direction, the channel layer 334 connecting the first S/D junction region 332 and the second S/D junction region forms a vertically arranged channel transistor in a 4F² DRAM device. The second S/D junction region will be connected to a bit line in the given example scheme. The channel layers 334 are each surrounded by the main gate dielectric layers 316 or the back gate dielectric layers 322 in the X and Y directions. The first S/D junction regions 332 may be connected to the storage node contact 306. The channel layers 334 may be formed of silicon (Si), silicon germanium (SiGe), polycrystalline Si, and oxide semiconductors. The channel layers 334 may be formed of a single crystal semiconductor material, such as single crystal silicon. The channel layers 334 may each have a thickness in the X direction of between about 3 nm and about 10 nm.

The method 200 begins with block 210, in which a dielectric recess process is performed to partially recess the second dielectric layer 314, the main gate dielectric layers 316, the third dielectric layer 320, and/or the back gate dielectric layers 322 from a top surface of the semiconductor structure 300 in the Z direction to partially expose a portion of the channel layer 334, as shown in FIG. 3B1. By the dielectric recess process, the second dielectric layer 314, the main gate dielectric layers 316, the third dielectric layer 320, and/or the back gate dielectric layers 322 are recessed to a depth of between about 1 nm and about 20 nm, for example, about 5 nm above the top edge of the main gates 312 in the Z direction. The intentionally placed gap between the recessed dielectric and the top edge of the main gate 312 is to minimize defect introduction into a gate controlled channel region. In some cases, as described below, the sidewalls of the channel layer 334 may not be directly exposed after the dielectric recess. The remaining layer may act as a protection layer for the channel layer to further reduce defect and/or oxidation.

The dielectric recess process may include any appropriate isotropic etch performed in a processing chamber, such as the processing chamber 120 shown in FIG. 1.

In a first embodiment, the second dielectric layer 314 is selectively recessed, and the main gate dielectric layers 316, the back gate dielectric layers 322, and the third dielectric layer 320 are not recessed, as shown in FIG. 3B2. Thus, one side of the channel layers 334 is exposed via the main gate dielectric layers 316.

In a second embodiment, the second dielectric layer 314, the main gate dielectric layers 316, the third dielectric layer 320, and the back gate dielectric layers 322 are all recessed, as shown in FIG. 3B3. Thus, the channel layers 334 are fully exposed (e.g., both sides of the channel layers 334 are exposed).

In a third embodiment, the back gate dielectric layers 322 and the third dielectric layer 320 are selectively recessed, and the main gate dielectric layers 316 and the second dielectric layer 314, as shown in FIG. 3B4. Thus, the channel layers 334 are partially exposed (e.g., both sides of the channel layer 334 near the back gate 318 are exposed, and one side of the channel layer 334 near the main gate 312 is exposed).

In block 220, an optional surface coating treatment is performed to reduce damage created during a subsequent implant process on the exposed surfaces of the channel layers 334.

In block 230, an ion implant process is performed to implant a dopant, such as phosphorus (P), into the exposed surfaces of the channel layers 334, forming first doped regions 336, as shown in FIG. 3C1. The first doped regions 336 will be low-to-medium doped junction regions of a vertically arranged channel transistor in a 4F² DRAM device.

The ion implant process may be a tilted hot implant process or a sidewall plasma implant (PLAD) process, performed in a processing chamber, such as the processing chamber 126, 128, 130, shown in FIG. 1. The ion implant process can be directional and thus the location of the first doped regions 336 can be adjusted. The low-to-medium dopant concentration may be between about 10¹⁷ cm⁻³ and about 10²⁰ cm⁻³.

In the first embodiment, an angled ion implant process implants a dopant through the main gate dielectric layer 316 into the surfaces of the channel layer 334, as shown by arrows in FIG. 3C2.

In the second embodiment, an angled ion implant process implants a dopant into the fully exposed surfaces of the channel layers 334, as shown by arrows in FIG. 3C3.

In the third embodiment, an angled ion implant process implants a dopant into the partially exposed surfaces of the channel layers 334, as shown by arrows in FIG. 3C4.

It should be noted that the channel layers 334 and the main gate dielectric layer 316 are thin (e.g., a few nanometers), and thus a low energy hot ion implant process suffices to dope the channel layers 334 with desired dopant concentration. The low energy ensures minimum damage is done to the channel material.

By the ion implant process in block 230, the desired amount of a dopant (e.g., phosphorus (P)) can be placed at a controlled depth into the exposed surfaces of the channel layers 334 without introducing defects.

In block 240, an optional laser anneal is performed to activate the implanted a dopant in the exposed surfaces of the channel layers 334. The anneal may also serve the purpose of healing defects introduced during the ion implant process.

In block 250, a dielectric fill process is performed to gapfill the first doped regions 336 with a fourth dielectric layer 338, as shown in FIG. 3D. The fourth dielectric layer 338 may be formed of silicon oxide (SiO₂), silicon nitride (Si₃N₄), silicon oxynitride (SiNₓO_{y}), silicon oxycarbide (SiOₓC_{y}), silicon-oxycarbonitride (SiOCN), a low-k material having a dielectric constant lower than that of the silicon oxide (SiO₂), or any combination thereof.

The dielectric fill process may be a CVD or ALD process that does not oxidize exposed surfaces of the first doped regions 336, for example, an oxidizer free flowable CVD (FCVD) process. The oxidizer free FCVD process does not oxidize silicon (Si) in the first doped regions 336 and thus does not consume silicon (Si) during the dielectric fill process. An optional chemical mechanical polishing (CMP) or an etch back (EB) process may be performed to planarize the surface of the semiconductor structure 300 and to expose the top surface of the first doped region 336.

In block 260, an optional recess process is performed to recess the first doped regions 336 within the fourth dielectric layer 338 from a top surface of the semiconductor structure 300 in the Z direction, creating self-aligned contact holes 340 in the fourth dielectric layer 338, as shown in FIG. 3E.

In block 270, an optional isotropic dielectric etch process is performed to enlarge the self-aligned contact holes 340.

In block 280, a lower temperature ALD or CVD process, for example, a low temperature epitaxial (epi) deposition process, is performed to form medium-to-high doped second S/D junction regions (also referred to as “second doped regions”) 342 within and above the self-aligned contact holes 340 in the fourth dielectric layer 338, as shown in FIG. 3F. The low temperature epi deposition process may be performed at a temperature of less than 450 °C. The second S/D junction regions 342 may be doped with medium-to-high concentration, such as higher than about 10¹⁹ cm⁻³ or about 10²⁰ cm⁻³, to enhance S/D hookup and to achieve low contact resistance Rc. In some cases, this portion of the second S/D junction regions 342 may have graded dopant concentration from about 10¹⁹ cm⁻³ to 10²¹ cm⁻³.The second S/D junction regions 342 will be connected to bit lines in a 4F² DRAM device in the given integration scheme.

The embodiments of the disclosure are described by way of example devices (e.g., a 4F² DRAM with vertical cell transistors) and processes for forming devices in accordance with one or more embodiments of the disclosure. The processes shown are merely illustrative possible uses for the disclosed processes, and the skilled artisan will recognize that the disclosed processes can be applied to other devices in which bitlines can be formed first for certain device design reasons low thermal budget is needed to form the junction for capacitors.

While the foregoing is directed to embodiments of the present disclosure, other and further embodiments of the disclosure may be devised without departing from the basic scope thereof, and the scope thereof is determined by the claims that follow.

1. A method of forming a semiconductor structure, comprising:
removing a portion of a first dielectric layer, which surrounds a plurality of channel layers, to expose portions of the plurality of channel layers;
implanting a dopant into the exposed portions of the plurality of channel layers to form a first doped region within each of the plurality of channel layers;
forming a second dielectric layer over the first doped regions; and
forming a second doped region on an exposed portion of each of the first doped regions disposed within the second dielectric layer.

2. The method of claim 1, wherein:
the plurality of channel layers comprise silicon (Si), and the first dielectric layer and the second dielectric layer each comprise silicon nitride, silicon oxide, silicon oxynitride, or any combination thereof,
the forming of the second dielectric layer comprises an oxidizer free flowable CVD process, and
the forming of the second doped regions comprises a low temperature epitaxial (epi) deposition process.

3. The method of claim 1, further comprising:
prior to implanting the dopant, performing a surface coating treatment on the exposed portions of the plurality of channel layers.

4. The method of claim 1, further comprising:
subsequent to implanting the dopant, performing a laser anneal process to activate the implanted dopant in the exposed portions of the plurality of channel layers.

5. The method of claim 1, further comprising:
subsequent to forming the second dielectric layer, performing a recess process to recess the first doped regions in the second dielectric layer to form self-aligned contact holes.

6. The method of claim 5, further comprising:
performing an isotropic dielectric etch process to enlarge the self-aligned contact holes.

7. A method of forming a semiconductor structure, comprising:
removing a portion of a first dielectric layer, which surrounds a plurality of channel layers, to expose portions of the plurality of channel layers;
implanting a dopant into the exposed portions of the plurality of channel layers to form a first doped region within each of the plurality of channel layers;
forming a second dielectric layer over the first doped regions;
recessing a portion of the first doped regions within the second dielectric layer, creating self-aligned contact holes in the second dielectric layer; and
forming second doped regions within the self-aligned contact holes in the second dielectric layer.

8. The method of claim 7, wherein:
the plurality of channel layers comprise silicon (Si), and the first dielectric layer and the second dielectric layer each comprise silicon nitride, silicon oxide, silicon oxynitride, or any combination thereof,
the forming of the second dielectric layer comprises an oxidizer free flowable CVD process, and
the forming of the second doped regions comprises a low temperature epitaxial (epi) deposition process.

9. The method of claim 7, further comprising:
prior to implanting a dopant, performing a surface coating treatment on the exposed portions of the plurality of channel layers.

10. The method of claim 7, further comprising:
subsequent to implanting a dopant, performing a laser anneal process to activate the implanted a dopant in the exposed portions of the plurality of channel layers.

11. The method of claim 7, further comprising:
performing an isotropic dielectric etch process to enlarge the self-aligned contact holes.

12. A method of forming a semiconductor structure, comprising:
partially recessing a first dielectric layer isolating main gates from a plurality of channel layers in a first direction, main gate dielectric layers isolating the main gates in a second direction that is orthogonal to the first direction, a second dielectric layer disposed on above and below back gages in the second direction, and back gate dielectric layers disposed on both sides of each of back gates in the second direction, to partially expose portions of the plurality of channel layers;
implanting a dopant into the exposed portions of the plurality of channel layers to form first doped regions;
forming a third dielectric layer over the first doped regions; and
forming a second doped regions on the first doped regions within the third dielectric layer.

13. The method of claim 12, wherein:
the plurality of channel layers comprise silicon (Si), and the first dielectric layer, the second dielectric layer, and the third dielectric layer each comprise silicon nitride, silicon oxide, silicon oxynitride, or any combination thereof,
the forming of the third dielectric layer comprises an oxidizer free flowable CVD process, and
the forming of the second doped regions comprises a low temperature epitaxial (epi) deposition process.

14. The method of claim 12, wherein the partially recessing comprising:
selectively recessing the first dielectric layer, and not recessing the main gate dielectric layers, the back gate dielectric layers, and the second dielectric layer.

15. The method of claim 12, wherein the partially recessing comprising:
selectively recessing the first dielectric layer, the main gate dielectric layers, the back gate dielectric layers, and the second dielectric layer.

16. The method of claim 13, wherein the partially recessing comprises:
selectively recessing the back gate dielectric layers and the second dielectric layer, and not recessing the main gate dielectric layers and the first dielectric layer.

17. The method of claim 13, further comprising:
prior to implanting the dopant, performing a surface coating treatment on the exposed portions of the plurality of channel layers.

18. The method of claim 13, further comprising:
subsequent to implanting the dopant, performing a laser anneal process to activate the implanted dopant in the exposed portions of the plurality of channel layers.

19. The method of claim 13, further comprising:
subsequent to forming the third dielectric layer, performing a recess process to recess the first doped regions in the third dielectric layer to form self-aligned contact holes.

20. The method of claim 19, further comprising:
performing an isotropic dielectric etch process to enlarge the self-aligned contact holes.
